(19) United States
(12) Patent Application Publication
(10) Pub. No.: US 2013/0130425 A1
(43) Pub. Date: May 23, 2013

(54) Method and Machine for Producing a Semiconductor, of the Photovoltaic or Similar Electronic Component Type

(71) Applicant: Jean-Pierre Medina, Meudon la Foret (FR)

(72) Inventor: Jean-Pierre Medina, Meudon la Foret (FR)

(21) Appl. No.: 13/637,926

(22) PCT Filed: Mar. 25, 2010
(86) PCT No.: PCT/FR2010/050541

§ 371 Date: Feb. 1, 2013

(30) Foreign Application Priority Data
Mar. 27, 2009 (FR) 0951946

(51) Int. Cl. H01L 21/78; H01L 31/18

(52) U.S. Cl. CPC H01L 21/78; H01L 31/1876
USPC 438/68; 29/25.01; 438/458

(57) ABSTRACT

The invention relates to a method for producing a semiconductor, of the photovoltaic cell type, or similar electronic components. According to the invention, at least one silicon wafer is cut from the cross-section of a silicon rod and, after doping, a substrate is assembled on either side of the silicon wafer and the latter is cut into two parts through the thickness of the silicon, so as to form two semiconductor units each comprising a substrate and a thin silicon film.

The present invention relates to a method and machine for producing semiconductor units, notably photovoltaic cells, as well as to a semiconductor unit obtained by such a method.

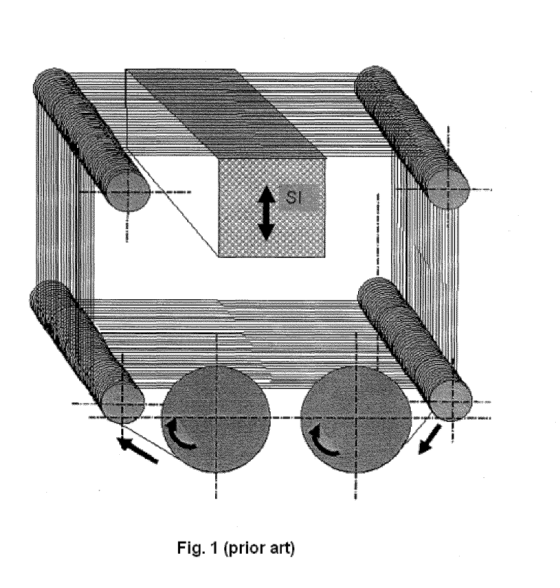

The constant and increasing time-dependent change in present energy needs is expressed by an intention and a search for new resources capable of protecting the environment. Solar energy is part of the preferential responses to this subject. Confronted with the rise in the prices of fossil energy, solar technology appears as a cost-effective and competitive industrial alternative. Therefore a goal of the manufacturers of photovoltaic cells and solar panels producing electric current is to reduce the costs for producing and setting up these devices. One of the essential constitutive elements of a photovoltaic cell is silicon, which is also used for manufacturing other electronic components. Now, silicon represents roughly one third of the price of the photovoltaic cell as manufactured presently. This is notably explained by the fact that in order to produce a photovoltaic cell, a thickness of about 400 to 450 μm of silicon is generally required. Indeed, in the conventional manufacturing process, a silicon ingot or bar is taken, generally with a size of 30 cm wide by 130 cm long, and wafers or discs of silicon are cut by means of a wire, the diameter of which is generally comprised between 160 and 200 μm. FIG. 1 illustrates a device of the prior art of this type. The wire which may have a length of several hundreds of kilometers, is wound around the bar and during a cutting or sawing process which takes about 7 hours, this bar will be cut into wafers each with a thickness from 150 to 200 μm. It is not possible to reduce the thickness of the wafers since otherwise the risk of breakage is too significant. Also, it is not possible to reduce the diameter of the wire which otherwise also risks breaking. Thus, by adding the thickness of the wire (160-200 μm) to the thickness of each wafer (150-200 μm), as well as to the losses of the order of 50 μm on average due to the handling operations of very fragile wafers, a thickness of about 450 μm of silicon for making a cell is attained. Now, a cell having a thickness from 150-200 μm does not have an optimum yield. Indeed, the optimum yield for silicon is obtained when the thickness of the silicon layer is of the order of 50 μm to 60 μm. With the conventional manufacturing method described above, it is impossible to make such a device. Thus, conventional methods are costly in silicon while not allowing the making of cells for which the yield would be optimum. Documents US 2008/245 408, US 2004/066 634, U.S. Pat. No. 6,870,087 and U.S. Pat. No. 6,534,382 describe systems and methods of the prior art. The object of the present invention is to provide a method and a machine for manufacturing semiconductor units, notably photovoltaic cells which do not reproduce the aforementioned drawbacks.

The object of the present invention is notably to provide such a semiconductor unit which is less costly to manufacture.

The object of the present invention is also to provide such a semiconductor unit, requiring less silicon for its making.

The object of the present invention is also to provide a method and a machine of this type, with which a semiconductor unit may be made, for which the yield is greater than that obtained by conventional manufacturing methods.

The object of the present invention is also to provide a manufacturing method and machine which are safe and reliable, while limiting the risks of breakage.

The object of the present invention is also to provide a method and a machine for manufacturing semiconductor units, allowing the use of both polycrystalline silicon and of single-crystal silicon.

The object of the present invention is a method for manufacturing semiconductor units, including the steps of providing a silicon bar, of cutting at least one silicon wafer in the cross-section of said silicon bar, of assembling a substrate on either side of said silicon wafer, and of cutting in the thickness in the middle of said silicon wafer, in order to form two semiconductor units each including a substrate and a thin silicon layer.

Advantageously, the silicon bar has a circular or square section, preferably with a width of about 300 mm and a length from about 500 mm to 1,300 mm.

Advantageously, the step for cutting at least one silicon wafer is carried out by sawing by means of a wire, notably a steel wire with an abrasive lubricant.

Advantageously, the step for cutting in the middle of the silicon wafer is carried out by sawing by means of a wire, notably a steel wire with an abrasive lubricant.

Advantageously, said wire has a diameter comprised between 80 μm and 130 μm, advantageously between 100 μm and 120 μm.

Advantageously, said at least one silicon wafer has a thickness comprised between 180 μm and 280 μm advantageously between 200 μm and 250 μm, and the thin silicon layer of each semiconductor unit has a thickness comprised between 40 μm and 80 μm, advantageously between 50 μm and 60 μm.

Advantageously, said substrate is a metal or insulating substrate preferably with a thickness comprised between 100 μm and 300 μm.

Advantageously, the substrate is in metal, notably in an iron and nickel alloy with an expansion coefficient close to that of silicon.

Advantageously, said substrate is an electrical insulator with an expansion coefficient close to that of silicon.

Advantageously, the step for assembling a substrate on each side of said silicon wafer is carried out by adhesive bonding.

Advantageously, said adhesive bonding is carried out with a conducting adhesive, such as a conducting ink or a silver film.

Advantageously, the step for assembling a substrate on each side of said silicon wafer is carried out at low temperature and/or in vacuo and/or under pressure.

Advantageously, before the step for assembling a substrate, the method includes the step for cleaning each silicon wafer, notably by rinsing and drying.

Advantageously, before the step for assembling a substrate, the method includes the step for doping each silicon wafer notably with N or P doping, notably by immersion in a bath containing boron or phosphorus.

Advantageously, the step for cutting in the thickness in the middle of the silicon wafer is carried out by applying positive and/or negative pressure, notably by means of electromagnetic and/or pneumatic and/or mechanical forces, on the assembled substrates on each side of the wafer.

Advantageously, after the step for cutting in the middle of the wafer, the method comprises carrying out at least one surface treatment of the silicon surface of each semiconductor unit, as well as a structuration and/or anti-reflective treatment.

Advantageously, a doping step, notably a P doping step, is carried out on the silicon surface of each semiconductor unit, after the step for cutting in the middle of said silicon wafer.

Advantageously, the step for providing a silicon bar comprises the doping of said bar in the core, notably by N or P doping.

Advantageously, said silicon is single-crystal or polycrystalline silicon.

Advantageously, the method is a method for manufacturing a photovoltaic cell, further including the step for applying electric connections on each semiconductor unit.

Advantageously, said step for applying electric connections is carried out by notably applying by screen printing, notably with conducting inks, conducting microcircuits on the silicon surface.

Advantageously, said step for applying electric connections comprises the piercing of a network of micro-perforations, notably by micro-sanding, in the silicon layer and the substrate, and inserting into each perforation a conductor suitable for collecting the current at the surface of the silicon and transmitting it to the rear of the substrate.

Advantageously, each connection includes an electrically conducting element inserted into an insulating frusto-conical sleeve.

Advantageously, the semiconductor unit is positioned in a chassis including a front face closed by a glass wall protecting the silicon surface, and an insulating rear face provided with ventilation orifices.

The object of the present invention is also a manufacturing machine in order to apply the method above, comprising means for providing a silicon bar, means for cutting at least one silicon wafer in the cross-section of said silicon bar, means for assembling a substrate on each side of said silicon wafer, and means for cutting in the thickness in the middle of said silicon wafer, in order to form two semiconductor units each including a substrate and a thin slice of silicon.

The object of the present invention is also a semiconductor unit made with the above manufacturing method, including a substrate, preferably a metal substrate, on which a thin silicon layer is applied.

Advantageously, said thin silicon layer has a thickness from 40 μm to 80 μm, preferably from 50 μm to 60 μm.

Advantageously, said unit is a photovoltaic cell for which the yield is greater than 15%, advantageously greater than 8%, preferably greater than 20%.

These features and advantages as well as other ones of the present invention will become more clearly apparent during the following detailed description, made with reference to the appended drawings, given as non-limiting examples, and wherein:

FIG. 1 is a schematic view of a method for manufacturing silicon wafers according to a conventional method of the prior art,

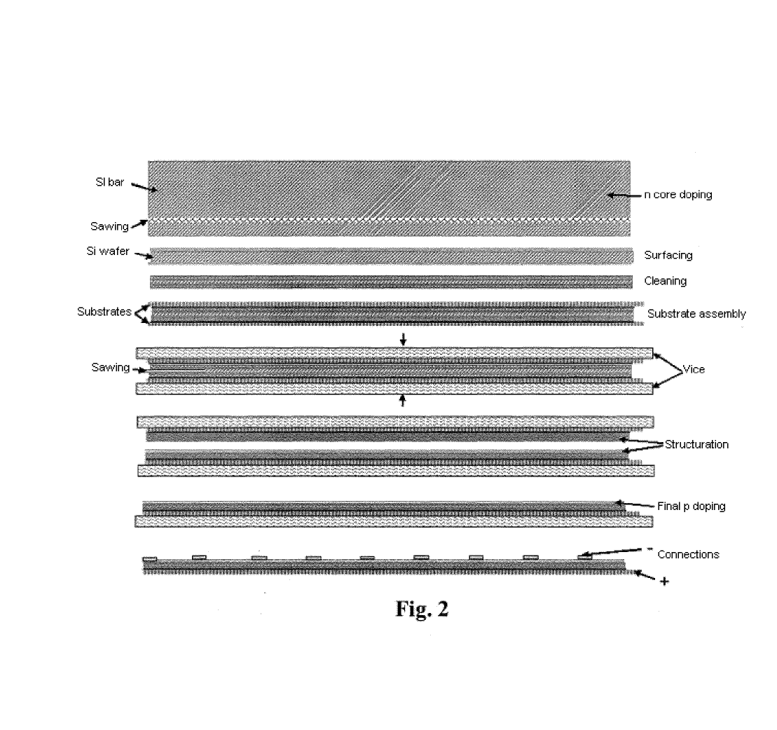

FIG. 2 schematically shows from top to bottom successive sequences of a manufacturing method according to an advantageous embodiment of the present invention,

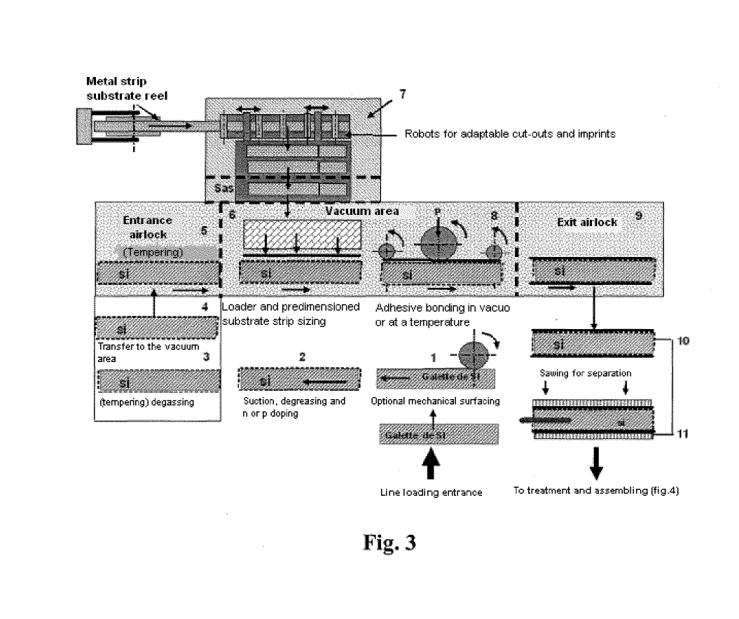

FIG. 3 is a diagram which shows different steps numbered from 1 to 11 in the manufacturing method according to an advantageous embodiment of the present invention,

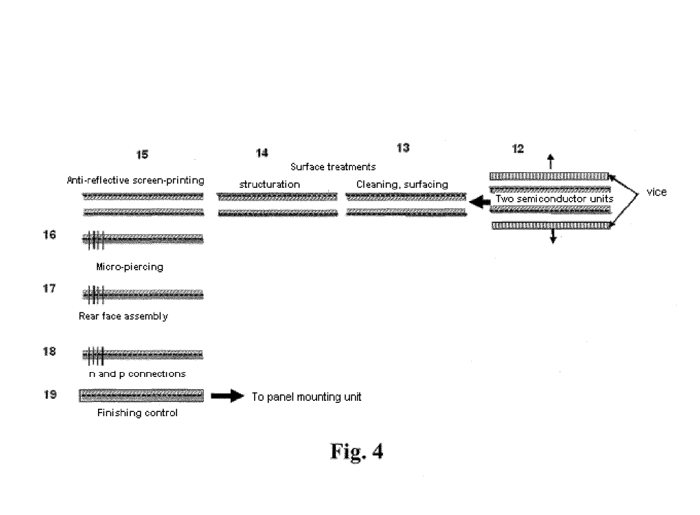

FIG. 4 is a diagram showing the following steps numbered from 12 to 19 of the manufacturing method according to an advantageous embodiment of the present invention,

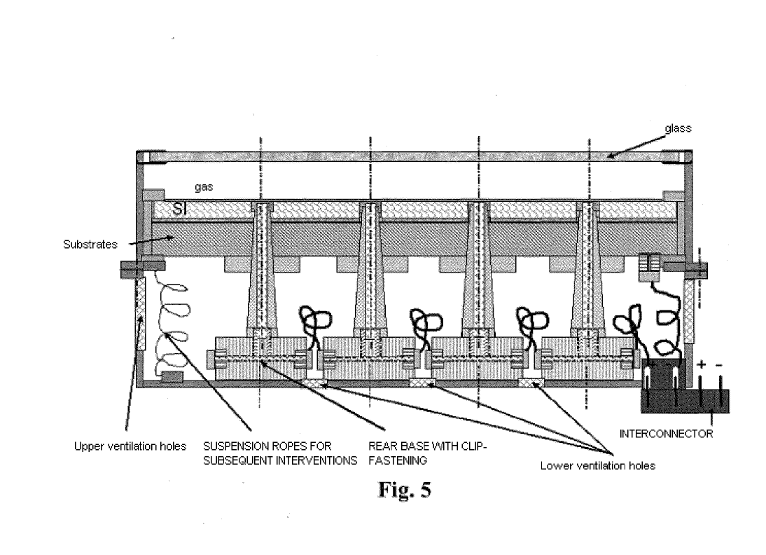

FIG. 5 is a schematic cross-sectional view of a photovoltaic cell made according to an advantageous embodiment of the present invention,

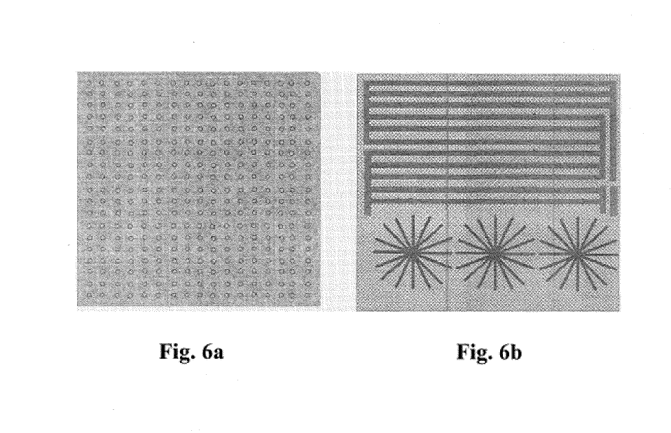

FIGS. 6a and 6b are top views of two alternative embodiments of the electric connections on the silicon surface of a photovoltaic cell, according to the present invention.

With reference to the figures, the method of the invention which will be described hereafter, as well as the manufacturing machine for applying this method, will mainly be described with reference to the manufacturing of a photovoltaic cell. However, it is understood that the present technology may also be applied to the manufacturing of other electronic components, such as diodes for example.

The method of the present invention consists of using a silicon bar or ingot, which may be of a standard size, with a section of about 300 mm×300 mm and a length from 500 mm to 1,300 mm. This bar may have a circular or square cross-section, or even a cross-section of a different shape. The method then provides the cutting out of the silicon wafers or chips or discs from said bar, in its cross-section, with preferably a thickness from about 200 μm to 250 μm. A substrate is then assembled on each side of each wafer and the wafer is then cut in its thickness, preferably in its center, in order to thereby form two semiconductor units each consisting of a substrate and of a thin silicon layer.

Notably referring to FIG. 2, surfacing and cleaning of the wafer are carried out preferably before assembling the substrates. Before cutting the wafer in the thickness in its middle, surface cleaning is advantageously carried out, as well as doping the silicon surface (N or P doping, with boron or phosphorus), by a suitable method. Next, a metal or insulating substrate with an expansion coefficient close to that of silicon, is assembled on each side of said wafer. After attachment by a suitable method, the wafer is cut, in the direction of its section and preferably at the middle of the thickness of the silicon, in order to thereby form two semiconductor units each consisting of a substrate and of a thin layer of silicon with a thickness as close as possible to the thickness of the silicon for optimum yield.

Performing a cut in the thickness of the silicon causes breakage of the surface layer of the initial doping and therefore of the electric conductivity between the rear portion of the substrate and the front surface of the silicon left free.

The structuration of the front surface of the silicon is accomplished by a suitable method, and it is then preceded with the application of an anti-reflective layer by a suitable method.

The setting into place of the collector circuit by screen printing, or by any other suitable method is accomplished as well as of the electric connections.

It should be noted that the silicon bar is preferably doped in the core, notably by N and/or P doping, before it is cut into a wafer.

Advantageously, the cutting of the wafers, as well as the cutting out of two semiconductor units, is achieved by means of a wire, notably a steel wire, preferably with addition of an abrasive lubricant, for which the diameter is advantageously of about 100 μm to 120 μm. Depending on the uses, a diameter slightly greater or slightly smaller may also be contemplated, for example from 80 μm to 130 μm. Advantageously, each cut-out wafer has a thickness of about 200 to 250 μm. Here also, depending on the needs, a greater or smaller thickness may be provided, for example from 180 μm to 280 μm. Thus, with a thickness from 200 to 250 μm for each wafer, and a thickness of the wire of about 100 μm, after cutting, two semiconductor units are obtained at the center of each wafer, each having a substrate and a thin silicon layer for which the thickness will be from about 50 to 60 μm. The most favorable thickness is thereby obtained for optimum yield of a photovoltaic cell. Because a substrate is attached on each side of the wafer and firmly held by a suitable method, during the cutting step, there is very little risk of the thin silicon layer breaking during this cutting step. With the present invention, it is therefore possible to provide a safer and more reliable manufacturing method, and to produce a semiconductor unit having optimum dimensions and features, so as to be made as a photovoltaic cell.

The substrate is preferably made as a strip which may have a thickness comprised for example between 100 μm and 200 μm. Preferably this strip is in metal, notably in an iron and nickel alloy, having an expansion coefficient close to that of silicon, for example FeN42. Other materials, notably other metals, may be contemplated for the substrate. The assembling of the substrate on each side of the silicon wafer may be achieved by adhesive bonding, notably by using a conducting adhesive such as a conducting ink or a silver film. In this application, because of the conducting nature of the adhesive, the substrate may even be made in an insulating material. Preferably, the assembling of the substrate on the silicon wafer is carried out at low temperature and/or in vacuo and/or under pressure.

The cleaning step which is preferably carried out on the wafer before assembling the substrate may include rinsing and drying. Also, the surfacing indicated in FIG. 2 may be associated with doping by immersion as described above. Alternatively the doping may also be achieved by cutting through the wafer in order to produce both semiconductor units.

Advantageously, the step for cutting the wafer is carried out by applying a positive and/or negative pressure, symbolized by the two arrows in FIG. 2, on the substrates. This positive and/or negative pressure may be achieved by means of electromagnetic forces, notably magnets, and/or by means of pneumatic and/or mechanical forces combined with air suction, for example by a vacuum or a suction cup. In this way, the assembly forming a sandwich is both firmly held during the cutting while maintaining apart both cut portions, thereby facilitating the passage of the wire and therefore reducing the risks of breakage of the silicon. After cutting and producing the two semiconducting units, it is advantageous to provide at least one surface treatment of the silicon surface of each semiconducting unit, such as for example a surface structuration and/or an anti-reflective treatment.

The present invention therefore allows a significant reduction in the consumption of silicon, since instead of using on average about 450 μm of silicon thickness per cell, less than the half of this is used for obtaining two cells with a higher yield since having a thickness close to or equal to the optimization of 50 μm to 60 μm.

Consequently, the present invention by the savings which it generates, makes the use possible of single-crystal silicon, known to be more performing, but also more costly than polycrystalline silicon. However, by the saving of silicon obtained by means of the present invention, the overcost of the single crystal is widely compensated. In fact, the use of single-crystal silicon again gives the possibility of further improving the yield of the photovoltaic cell obtained by the present invention.

Another advantage relatively to the method of the prior art is that in the conventional system, it is necessary to chamfer the edges of each silicon disc or wafer in order to avoid short circuits between the positive and negative terminals of the electric circuit. Because of the cutting of the wafer in its thickness, in order to create two separate semiconducting units, with the present invention, it is possible to avoid this phase for cutting the peripheral edge of the wafer, this tends to reduce the manufacturing costs.

In order to produce a photovoltaic cell from the semiconducting unit obtained as described above, electric connections are applied. In the example of FIG. 2, positive and negative terminals are respectively applied on the front face in silicon and the rear face of the substrate. FIG. 6b shows an example of a circuit affixed by screen printing, notably by means of a conducting ink, on the silicon surface in order to collect the electric current. Of course, the graphics of such a circuit on silicon reduces by about 14 to 17% the useful effective surface area of a photovoltaic cell in silicon for producing current. The present invention therefore advantageously provides that so-called “rear” connections be made in order to reduce the so-called “dead” surfaces for still further increasing the exposed active surface area of the cell. To do this, a bundle of micro-perforations may be produced, notably by micro-sanding, in the silicon layer and in the substrate. Partly insulated micro-conductors, may be inserted into each micro-perforation in order to collect the current at the surface of the silicon and for transmitting it to the rear of the substrate. This application is more clearly illustrated in FIG. 5, which shows that each conductor may include a conducting wire for example inserted in a frusto-conical and insulating sleeve. FIG. 6a illustrates a top view of such a network of micro-perforations on the silicon layer. With this application, the useful surface area of the silicon is increased as compared with the traditional screen-printed circuit.

In order to combat the rise in temperature of the cell, which is a penalty factor since the yield of the cell decreases with the rise of its temperature, ventilation is advantageously provided, either by air or by a heat transfer circuit. To do this, the chassis in which the photovoltaic cells are assembled, advantageously includes ventilation orifices provided on its rear face, as visible in FIG. 5. On the other side of the front face of the chassis, a glass wall is positioned in order to protect the cells. Optionally a second glass plate may be interposed between the external protective wall and the silicon surface.

FIGS. 3 and 4 schematically illustrate the manufacturing method and the manufacturing machine for applying this method starting from the silicon wafer obtained by cutting the silicon bar, the optional mechanical surfacing of which forms the step having reference 1. Subsequently, this silicon wafer is subject to suction, to degreasing and optionally to doping, as indicated by step 2. The silicon wafer is then tempered in step 3, and then transferred to an area in vacuo in step 4. In the entry phase of step 5, it is again tempered in order to be brought into the vacuum area where the metal strips will be applied on both sides of the wafer for forming the substrates. The machine for making the substrates is schematically referenced by reference 7. The vacuum area therefore includes a loader and sizing of the predimensioned substrates on the wafer in vacuo or by temperature or by pressure, as described earlier, as illustrated by step 8. The wafer provided with both of its substrates forming the sandwich structure is then transferred into the exit airlock 9, and then in steps 10 and 11, the wafer is sawn in its thickness in order to form both semiconducting units. FIG. 4 illustrates the continuation of the method for making the photovoltaic cell. Thus, in step 12, the vice which maintains both units together during the sawing step is loosened and both semiconducting units are therefore obtained, which are then cleaned, surface-treated, structured according to needs (steps 13 and 14), as well as subject to anti-reflective treatment, as indicated by step 15. And then the screen-printing and the making of electric connections on the silicon take place. This may be achieved during the same step 15, simultaneously.

Alternatively, step 16 provides micro-piercing of the micro-perforations in order to achieve the so-called rear connections as indicated in steps 16 and 17. Steps 18 and 19 consist in finishing and checking before transferring the cell to assembling in a panel.

With this application, the present invention gives the possibility of providing photovoltaic cells, for which the yield is comprised between 15% and 20%, or even more, which places this product among the most performing, with a manufacturing cost clearly less as compared with present cells.

It should be noted that the invention was described with reference to silicon, but it is clear that other materials having equivalent properties may also be used.

Although the present invention was described with reference to a particular embodiment thereof, it is understood that various modifications may be contemplated for one skilled in the art without departing from the scope of the present invention as defined by the appended claims.

1. A method for manufacturing semiconducting units, comprising:
providing a silicon bar;
cutting out at least one silicon wafer in the cross section of said silicon bar;
assembling a substrate on each side of said silicon wafer; and
cutting in the thickness in the middle of said silicon wafer, in order to form two semiconducting units each including a substrate and a thin silicon layer.

2. The method according to claim 1, wherein said silicon bar has a circular or square section with a width of about 300 mm, and a length of about 500 mm to 1,300 mm.

3. The method according to claim 1, wherein cutting out at least one silicon wafer is achieved by sawing with a steel wire with an abrasive lubricant.

4. The method according to claim 1, wherein cutting in the middle of the silicon wafer is achieved by sawing with a steel wire with abrasive lubricant.

5. The method according to claim 3, wherein said steel wire has a diameter comprised between 80 μm and 130 μm.

6. The method according to claim 1, wherein said at least one silicon wafer has a thickness between 180 and 200 μm, and the thin silicon layer of each semiconducting unit has a thickness between 40 μm and 80 μm.

7. The method according to claim 1, wherein said substrate is a metal or insulating substrate with a thickness between 100 μm and 300 μm.

8. The method according to claim 7, wherein the substrate is in an iron and nickel alloy with an expansion coefficient close to that of silicon.

9. The method according to claim 7, wherein said substrate is electrically insulated with an expansion coefficient close to that of silicon.

10. The method according to claim 1, wherein assembling a substrate on each side of said silicon wafer is carried out by adhesive bonding.

11. The method according to claim 10, wherein said adhesive bonding is carried out with a conducting adhesive.

12. The method according to claim 1, wherein assembling a substrate on each side of said silicon wafer is carried out at a low temperature and/or in vacuo and/or under pressure.

13. The method according to claim 1, wherein, before assembling a substrate, the method includes cleaning each silicon wafer by rinsing and drying.

14. The method according to claim 1, wherein, before assembling a substrate, the method includes doping each silicon wafer with N or P doping by immersion in a bath containing boron or phosphorus.

15. The method according to claim 1, wherein cutting into the thickness in the middle of the silicon wafer is carried out by applying a positive and/or negative pressure via electromagnetic and/or pneumatic and/or mechanical forces, on the assembled substrates on each side of the wafer.

16. The method according to claim 1, wherein, after cutting in the middle of the wafer, the method comprises carrying out at least one surface treatment of the silicon surface of each semiconducting unit.

17. The method according to claim 1, wherein P doping is carried out on the silicon surface of each semiconducting unit, after cutting in the middle of said silicon wafer.

18. The method according to claim 1, wherein providing a silicon bar comprises the doping of said bar, in the core by N or P doping.

19. The method according to claim 1, wherein said silicon is single-crystal or polycrystalline silicon.

20. A method for manufacturing a photovoltaic cell, comprising a method according to claim 1, and further including:
applying electric connections on each semiconducting unit.

21. The method according to claim 20, wherein applying electric connections is carried out by applying by screen printing with conducting inks, conducting micro circuits on the silicon surface.

22. The method according to claim 20, wherein applying electric connections comprises piercing a network of micro perforations by micro sanding, in the silicon layer and the substrate, and inserting into each perforation a conductor suitable for collecting the current at the surface of the silicon and transmitting it to the rear of the substrate.

23. The method according to claim 22, wherein each connection includes an electric conducting element inserted in an insulating frusto-conical sleeve.

24. The method according to claim 1, wherein the semiconducting unit is positioned in a chassis including a front face closed by a glass wall protecting the silicon surface, and an insulating rear face provided with ventilation orifices.

25. Manufacturing machines for applying the method according to claim 1, comprising:
means for providing a silicon bar;
means for cutting out at least one silicon wafer in the cross section of said silicon bar;
means for assembling a substrate on each side of said silicon wafer; and
means for cutting into the thickness of the middle of said silicon wafer, in order to form two semiconducting units each including a substrate and a thin silicon slice.
